(19) United States
(12) Patent Application Publication
(10) Pub. No.: US 2026/0293071 A1
(43) Pub. Date: Sep. 24, 2026

(54) SYSTEM AND METHOD FOR SIMULTANEOUS ELECTRIC AND MAGNETIC FIELD SUPPRESSION IN RADIANT HEATING DEVICES

(71) Applicants: Adam Fischer, San Diego, CA (US); Tyler Fish, San Diego, CA (US); Feffrey H. Fischer, San Diego, CA (US)

(72) Inventors: Adam Fischer, San Diego, CA (US); Tyler Fish, San Diego, CA (US); Feffrey H. Fischer, San Diego, CA (US)

(21) Appl. No.: 19/575,685

(22) Filed: Mar. 23, 2026

Related U.S. Application Data
(60) Provisional application No. 63/773,470, filed on Mar. 18, 2025.
(60) Provisional application No. 63/865,533, filed on Aug. 17, 2025.

(51) Int. Cl. H05K 9/00; H05B 3/02

(52) U.S. Cl. CPC H05K 9/002; H05B 3/02

(57) ABSTRACT

A system for reducing EMF emissions in radiant heating devices comprises paired heating elements, such as halogen infrared tubes or carbon strips, configured to operate with reversed current directions to substantially cancel magnetic field emissions. A conductive shield, fabricated from a metallic material such as aluminum, copper, or stainless steel, is positioned between the heating elements and the user-occupied space and is electrically connected to earth ground to suppress electric field emissions. The combination of magnetic field cancellation through phase-inverted current flow and electric field attenuation via grounded shielding enables the simultaneous reduction of both electric and magnetic field components during normal operation. The system is suitable for use in infrared saunas, space heaters, and other AC- or DC-powered radiant heating applications, and may include control circuitry to manage current phasing, real-time EMF monitoring, and user-selectable EMF mitigation modes.

### BACKGROUND OF THE INVENTION

### Field of Invention

The present invention pertains to the field of electric and magnetic field mitigation in radiant heating systems. As used herein, the term EMF refers to electric fields and magnetic fields; while EMF is sometimes used to denote electromagnetic fields (which are radiating fields), this disclosure is directed to non-radiating electric and magnetic fields only. More specifically, the invention relates to heating apparatuses, such as those utilizing halogen heating elements, wherein coupling and emissions comprising both electric field and magnetic field components are concurrently suppressed. The invention is directed to systems and methods that employ phase-inverted electrical current in paired heating elements in conjunction with a grounded conductive shield, thereby reducing EMF exposure associated with the operation of radiant heaters. Applications include, but are not limited to, infrared sauna systems, residential and commercial space heaters, and other electrically powered radiant heating devices.

### Description of the Related Art

Radiant heating devices are widely used in a variety of applications including residential space heaters, infrared sauna heaters, industrial drying equipment, and outdoor infrared heating systems. Many such devices utilize electrically powered heating elements, such as halogen infrared tubes, carbon fiber heating elements, or other resistive heating structures, that generate radiant heat when energized by an alternating current (AC) power source.

When electrical current flows through a heating element, electric and magnetic fields are generated as a natural consequence of current flow and voltage potential. These fields include magnetic field components produced by the current flowing through the heating elements and electric field components associated with the applied voltage. In many heating devices, particularly those employing high-power heating elements or multiple heating elements, the resulting electric and magnetic field emissions may extend into the surrounding environment.

In conventional radiant heating devices, heating elements are typically connected to a power source using electrical wiring that does not consider the orientation of current flow with respect to nearby heating elements or wiring paths. As a result, magnetic fields generated by adjacent heating elements and associated wiring may reinforce each other rather than cancel. Additionally, many conventional heater designs lack structures configured to reduce electric field emissions originating from energized heating elements.

Various attempts have been made to reduce electric and magnetic field emissions in electrical devices, such as by shielding electrical components or modifying electrical wiring arrangements. However, such approaches often address only a single component of these emissions, or they introduce additional complexity, cost, or reduced heating performance. For example, some shielding approaches may reduce electric field emissions but do not address magnetic field emissions generated by current flow through heating elements.

Further, some heater configurations may attempt to reduce electric and magnetic field emissions by modifying the arrangement of heating elements; however, these designs may reduce available heating power or may not effectively reduce electric and magnetic fields across the range of operating conditions encountered in typical radiant heating systems.

Accordingly, there exists a need for improved systems and apparatuses for radiant heating devices that are capable of reducing electric and magnetic field emissions while maintaining efficient heating performance. In particular, there is a need for heating systems in which heating elements and associated circuitry are arranged and controlled in a manner that reduces magnetic field emissions generated by current flow while also reducing electric field emissions associated with energized heating elements.

### BRIEF SUMMARY OF THE INVENTION

The present invention provides a system and apparatus for reducing EMF emissions in radiant heating devices. The system is particularly applicable to radiant heaters that utilize electrically powered heating elements, such as halogen infrared tubes, carbon heating elements, or carbon fiber heating elements, which generate heat when energized by an alternating current (AC) power source.

In some embodiments, the system includes an even number of heating elements arranged in pairs. Each pair includes a first heating element and a second heating element disposed in a spaced configuration relative to each other. A feed circuit is operatively connected to the heating elements and is configured to supply electrical current to the first heating element in a first direction and to the second heating element in a second direction opposite to the first direction. By supplying current in opposing directions through paired heating elements, magnetic fields generated by the respective current flows may partially or substantially cancel in the surrounding environment.

In some embodiments, the magnetic field of a single heating element may be canceled by routing its return feed wire in close proximity to and parallel with the heating element, such that the return wire carries current in the opposite direction to the current flowing through the heating element, causing their respective magnetic fields to at least partially cancel in the surrounding environment.

In some embodiments, the system further includes a conductive shield disposed between the heating elements. The conductive shield may be fabricated from a conductive material such as aluminum, copper, stainless steel, or other electrically conductive alloys. The conductive shield is electrically connected to earth ground by a grounding conductor. The grounded conductive shield reduces electric field emissions generated by the energized heating elements.

Through the combination of opposing current flow in paired heating elements and the use of a grounded conductive shield, the system reduces both magnetic field and electric field components of EMF generated during operation of the radiant heating device.

In some embodiments, the feed circuit may include a microcontroller configured to control the polarity, phase, or amplitude of electrical current supplied to the heating elements in order to improve magnetic field cancellation. In other embodiments, the radiant heating device may further include a conductive enclosure surrounding at least a portion of the heating device to provide additional electric and magnetic field shielding.

The disclosed system may be used in various radiant heating applications including infrared sauna heaters, residential or commercial space heaters, outdoor radiant heaters, and other electrically powered heating devices where reduction of EMF is desirable.

### BRIEF DESCRIPTION OF THE FIGURES

FIG. 1 illustrates a method for reducing EMF emissions in a radiant heating system through the paired arrangement of heating elements in accordance with some embodiments of the present disclosure;

FIG. 2 illustrates a block diagram of an example configuration of a radiant heating system configured to reduce EMF emissions in accordance with some embodiments of the present disclosure;

FIG. 3 illustrates an example electrical configuration of paired heating elements connected in a parallel arrangement in a radiant heating device configured to reduce EMF emissions in accordance with some embodiments of the present disclosure; and

FIG. 4 illustrates another example electrical configuration of paired heating elements connected in a series arrangement in a radiant heating device configured to reduce EMF emissions in accordance with some embodiments of the present disclosure.

Like reference numerals refer to like parts throughout the several views of the drawings.

### DETAILED DESCRIPTION

The present invention relates to a system and method for substantially reducing EMF emissions from radiant heating devices through a dual-action mitigation architecture that simultaneously addresses both magnetic and electric field components. The invention is particularly applicable to radiant heaters, such as halogen quartz tubes or carbon strip heaters, operating with alternating current (AC) or direct current (DC) power sources, wherein EMF exposure has been identified as a source of regulatory and consumer concern. In the context of non-propagating, low-frequency systems such as AC-powered heaters operating at 50 or 60 Hz, the electric and magnetic field components are, for the most part, near-field and decoupled, and thus require distinct suppression mechanisms to effectively reduce the total EMF exposure.

In accordance with a preferred embodiment of the invention, the system comprises a plurality of radiant heating elements arranged in pairs or any effective pairing made with the feed wire. Each heating element is an elongated tubular infrared emitter, typically constructed from a fused quartz or borosilicate glass envelope containing a halogen gas and an internal resistive filament, often tungsten, configured to emit infrared radiation when energized. As used herein, infrared radiation refers to the near, mid, and far infrared spectrum, spanning wavelengths from approximately 700 nm to 1 mm, though the relevant spectrum may extend somewhat beyond these bounds depending on the heating element and application. These elements may have diameters on the order of 8 mm to 25 mm and lengths on the order of 300 mm to 1,200 mm, depending on the heating application. The preferred operating voltage of the halogen heating elements may range from on the order of 110 VAC to 240 VAC, with nominal power ratings on the order of 250 watts to 2,000 watts per heating element.

In some embodiments, the heating elements are mounted in parallel pairs such that the first element of the pair (Element A) is supplied with an AC current flowing in one direction during the positive half-cycle of the AC waveform, while the second element of the pair (Element B) receives a current of equal magnitude but opposite direction. This phase-inverted configuration is achieved through one of several wiring techniques, including but not limited to the use of a center-tapped transformer, dual-phase wiring configurations, H-bridge inverter topologies, or polarity-reversing relay circuitry. The system may incorporate a phase synchronization circuit that ensures the current flowing through Element A is 180 degrees out of phase with the current through Element B during each AC cycle, thereby producing opposing magnetic field vectors. These magnetic fields, which under standard configurations would radiate outward from each heating element due to the current-induced magnetic flux, are substantially canceled by virtue of their spatial symmetry and phase opposition, in accordance with the Biot-Savart law and Maxwell's equations for time-varying fields. The separation distance between each heating element in the pair is often on the order of 5 mm to 100 mm, with a best separation determined by balancing field cancellation efficiency and thermal design constraints.

The effectiveness of magnetic field cancellation depends on relative distances rather than absolute dimensions. Cancellation quality is governed by the ratio of the element-pair separation distance to the measurement distance at which field strength is evaluated. For example, if paired heating elements are spaced 4 inches apart but the measurement point is only 2 inches away, the cancellation will be poor. Conversely, if the elements are spaced 2 inches apart and the measurement is taken at 4 inches away, significantly better and more spatially uniform cancellation is achieved. This principle applies equally to the spacing of supply wires: keeping opposing-current wire pairs closer together relative to the measurement distance improves cancellation at that distance. Because the governing factor is the ratio of separation to measurement distance, the design scales with dimensions—the same cancellation performance can be achieved at any physical scale provided the proportional relationships are maintained. The underlying physical basis for this geometric dependence is that magnetic flux line vectors cancel only to the extent that they are opposed in direction at the measurement point. At a measurement point that is close relative to the element separation, the flux vectors arriving from each paired element are not precisely antiparallel—they arrive at slightly different angles, meaning each vector has a component that aligns with, rather than opposes, the other. Those co-directed components do not cancel and contribute to residual field strength. As the measurement distance increases, normal to the alignment of the elements, relative to the element separation, the angular difference diminishes, the flux vectors become increasingly antiparallel at the measurement point, and cancellation becomes more complete. Maximizing cancellation therefore requires that the measurement distance be large relative to the element separation, so that the opposing flux vectors are substantially collinear and antiparallel at the point of evaluation. As used herein, the term “in close proximity,” as applied to the separation between two conductors, between a conductor and a heating element, or between paired heating elements, means that the separation distance between the two is less than half the distance from the pair to the nearest boundary of the user-occupied space. This definition ensures that meaningful magnetic field cancellation occurs within the user-occupied space, in accordance with the geometric cancellation principle described above.

In some embodiments, the heating elements may be housed in a thermally insulated enclosure fabricated from high-temperature-resistant materials such as powder-coated steel, anodized aluminum, or stainless steel alloys. The housing may include reflective surfaces composed of polished aluminum or silver-coated ceramic composites to maximize forward-directed infrared radiation while minimizing stray emissions. The reflectivity of these surfaces may exceed on the order of 90% in the visible-infrared spectrum (wavelengths on the order of 400 nm to 1 mm).

In some embodiments, to address the electric field component of EMF, the invention further comprises a conductive shielding structure that is electrically coupled to earth ground and interposed between the heating elements and the user-occupied space. As used herein, the term “user-occupied space” refers to the region outside the heater housing that is accessible to and occupied by persons during normal operation of the device, such as the interior of a sauna enclosure, the area in front of a space heater, or any other region where a person may be present and exposed to EMF emissions from the heating elements. The shielding structure may be configured in various geometries including flat, cylindrical cages, or conformal meshes, and may be composed of metallic materials possessing high electrical conductivity and possess the radiant heat. Suitable materials include, but are not limited to, aluminum (grade 1100 or 6061), copper (grades C10100 to C11000), brass (C26000), or stainless steel (AISI 304 or 316). The shielding element should exhibit a minimum conductivity on the order of 10\hat{ }6 S/m and may be fabricated with thicknesses on the order of 0.1 mm to 2 mm, depending on the mechanical and thermal requirements of the application.

In some embodiments, the conductive shield is electrically bonded to earth ground using a dedicated grounding conductor, compliant with national and international safety standards. The grounding connection may be routed through a low-impedance path, such as a copper grounding strap or braided wire, and tested to ensure continuity and resistance. The grounding system must also accommodate surge currents and fault conditions as required by local electrical codes.

In certain embodiments, the shield is supported on dielectric standoffs or thermally insulating spacers made from materials such as mica, ceramic, PTFE, or high-temperature silicone to electrically isolate the shield from the heating elements and structural frame while maintaining dimensional stability at elevated temperatures during continuous operation. In systems designed for sauna use, where ambient temperatures can reach or exceed temperatures on the order of 70° C., thermal expansion and emissivity must be factored into material selection. The coefficient of thermal expansion (CTE) of selected metals should be within acceptable tolerance to avoid warping or fatigue over repeated thermal cycles.

In some embodiments, an optional airflow management subsystem may be included to provide convective cooling across the shield and housing surfaces, particularly in high-wattage units. This subsystem may comprise one or more axial or tangential fans, thermally actuated louvers, or natural convection vents, strategically positioned to maintain housing surface temperatures below regulatory limits.

In some embodiments, the system may further include a control unit configured to regulate heater operation and improve EMF suppression performance. The control unit may include a microcontroller or digital signal processor (DSP) that monitors real-time electrical parameters such as current, voltage, phase angle, and frequency, and adjusts the polarity or timing of current delivery to the heating elements accordingly. The control system may also include feedback loops from EMF sensors or Hall-effect sensors positioned near the heating elements to provide real-time data on residual field strength. Control logic may be implemented using programmable firmware stored in non-volatile memory and capable of being updated via USB, serial interface, or over-the-air protocols for connected systems.

In some embodiments, phase-adjusting circuitry may be incorporated into the feed for at least one of the heating elements to differentially adjust the phase of the current supplied to that element, thereby improving magnetic field cancellation between paired elements. In some embodiments, the phase-adjusting circuitry comprises at least a series circuit element and a shunt circuit element on the feed line, the combination of which shifts the phase of the current reaching the heating element relative to the current supplied to its paired counterpart. This combination of series and shunt elements is referred to herein as a phase-shift network. By tuning the relative phase offset between paired heating elements, the opposing magnetic field vectors produced by each element can be brought into more precise opposition at the measurement point, reducing residual field strength beyond what is achievable by wiring reversal alone. In some embodiments, a microcontroller may adjust the phase-adjusting circuitry based on feedback from one or more magnetic field sensors positioned in proximity to the heating elements, enabling closed-loop improvement of magnetic field cancellation during operation. In some embodiments, such closed-loop feedback operates continuously during operation, with the microcontroller adjusting the phase-adjusting circuitry in real time based on sensor measurements. In other embodiments, the best phase adjustment may be determined during the design phase and input to the controller as a fixed setting, or realized through manual selection of component values, such that the phase-adjusting circuitry operates at a predetermined fixed offset without requiring active sensor feedback during operation.

In some embodiments, the invention may be configured to comply or be lower than with relevant EMF exposure limits and guidelines set by regulatory bodies including the International Commission on Non-Ionizing Radiation Protection (ICNIRP), the Institute of Electrical and Electronics Engineers (IEEE), the Federal Communications Commission (FCC), and the Occupational Safety and Health Administration (OSHA). The system may incorporate safety interlocks and diagnostic modes to detect grounding faults, broken shielding continuity, or improperly phased heating elements, issuing audible or visual alerts and automatically disabling the system until the fault is resolved.

In some embodiments, the mechanical structure of the heating module may be constructed in modular form, allowing independent replacement of heating elements, shields, and control electronics. Mounting brackets may be fabricated from anodized aluminum, polycarbonate, or high-temperature nylon, and designed to maintain heating element alignment to preserve magnetic field symmetry. The internal wiring should be rated for high temperature operation and secured with heat-resistant cable clips to prevent displacement or arcing.

In some embodiments, the entire system may be enclosed in a low-EMF composite enclosure with radiation shielding properties, or housed behind a transparent infrared-permeable panel made from tempered glass or polycarbonate with anti-reflective coatings. The shielding and housing materials must not significantly interfere with the infrared spectrum of interest to ensure best thermal transfer efficiency. Materials with infrared transmittance on the order of 85% or greater within the target wavelength range are preferred.

From a scientific perspective, the simultaneous mitigation of both electric and magnetic field components in the low-frequency (non-radiative) regime is achieved by decoupling the sources of field generation and applying distinct physical principles for suppression: magnetic field reduction is governed by Ampère's circuital law and the superposition principle, whereas electric field suppression follows Gauss's law for electricity and relies on electrostatic shielding and capacitive discharge pathways.

Alternative embodiments may substitute the halogen tube emitters with other radiant heating technologies, including but not limited to carbon fiber heating elements, ceramic infrared emitters, or nichrome resistive wire arrays, provided that the heating elements are compatible with AC power and exhibit similar EMF characteristics. The invention is likewise extensible to other heating applications beyond saunas and space heaters, including industrial drying systems, food warmers, laboratory incubators, and therapeutic heating beds.

This disclosure offers a robust, adaptable, and scientifically grounded solution to the persistent problem of EMF exposure in AC-powered radiant heating systems. Through the synergistic combination of current direction reversal in paired heating elements and the deployment of electrically grounded conductive shielding, the system achieves simultaneous suppression of both electric and magnetic field components of EMF without compromising thermal performance or system durability. The disclosed embodiments provide a comprehensive framework for manufacturing low-EMF heating devices that are suitable for safety-conscious consumers, regulatory compliance, and integration into next-generation health and wellness technologies.

In an alternative or supplemental embodiment, the system for EMF reduction further includes an enclosure-level conductive barrier configured to operate as a modified grounded shield, surrounding the heating assembly or the radiant heating device as a whole. This embodiment is designed to provide extended electric field shielding beyond localized shielding of the heating elements themselves, thereby attenuating residual or stray EMF components that may not be fully suppressed by proximal shielding structures or current-cancellation effects.

In some embodiments, the grounded shield may take the form of a continuous or partially enclosed conductive structure surrounding the heater housing, mounted either internally or externally relative to the outer frame of the radiant heating device. In certain configurations, this enclosure may be constructed from perforated sheet metal, expanded metal mesh, conductive fabric, or braided metallic shielding. Suitable materials for this structure include aluminum, copper, stainless steel, or conductive alloys exhibiting substantial electrical conductivity. The material selection may be guided by the specific thermal, mechanical, and electric and magnetic field shielding requirements of the application.

In some embodiments, the geometry of the grounded shield may include one or more panels, meshes, or conductive screens disposed adjacent to the heating assembly, forming a partial or complete conductive enclosure. In one example, a mesh shield may surround the heater module on all sides except the radiant output face, with conductive edges joined by low-resistance bonding strips or screws to maintain electrical continuity. In another example, a foil-laminated polymer sheet may line the interior of a sauna wall to form an enclosure-wide barrier that is electrically bonded to the grounded shielding of the heating system.

In all embodiments, the grounded shield must be electrically bonded to a common grounding point that satisfies applicable grounding requirements as set forth in standards such as UL 467, IEC 61000 May 2, and IEEE Std. 1100. This grounding connection may be made via braided copper strap, grounding terminal, or screw-in bonding stud, and should exhibit a low resistance to earth ground to ensure effective discharge of displaced charge and prevent electric field.

To prevent thermal obstruction or radiant energy loss, the grounded shield structure may include thermal openings, ventilation holes, or optically transparent windows made from infrared-permeable dielectric materials, such as borosilicate glass or polycarbonate, provided that such materials are not electrically conductive. In certain configurations, a dual-layer shielding system may be implemented, where the conductive structure is located externally to a primary shield near the heating elements, thereby providing a nested EMF suppression system.

In some embodiments, this layered shielding architecture enables a gradient-based attenuation profile, wherein primary EMF suppression occurs at the source through current cancellation and localized shielding, and secondary suppression occurs at the enclosure boundary via distributed capacitive containment.

In some embodiments, this grounded shield-based embodiment may be integrated with other subsystems, such as digital control modules or Wi-Fi control units embedded in the heater enclosure. These electronic subsystems may themselves emit high-frequency propagating electromagnetic fields, and may benefit from encapsulation within compartmentalized grounded shields or conductive enclosures bonded to the main grounding network of the system.

In embodiments designed for therapeutic or health-sensitive environments such as infrared saunas, the inclusion of an enclosure-wide grounded shield may be presented as an advanced feature offering comprehensive EMF mitigation beyond conventional industry practices. It may also serve as a visual or marketing distinction for low-EMF or EMF-safe certifications.

In some embodiments, the grounded shield-based embodiment provides additional or alternative EMF shielding functionality that complements the existing magnetic field suppression by current inversion and electric field suppression by localized grounded shielding. This embodiment may be employed independently or in combination with the previously described architecture, and it provides further design flexibility for high-sensitivity environments, high-wattage applications, and regulatory compliance scenarios requiring ultra-low EMF emission thresholds.

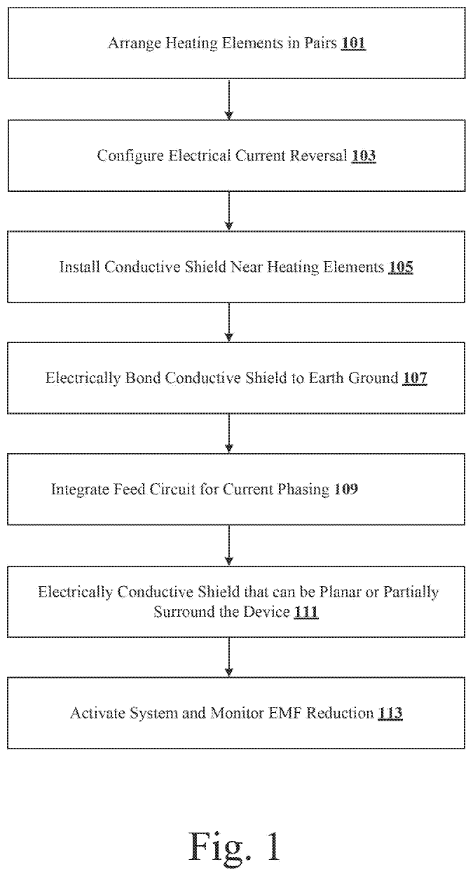

FIG. 1 illustrates an example operational sequence and system configuration for reducing EMF emissions in a radiant heating device. The illustrated sequence shows a method of arranging heating elements, configuring electrical current flow, installing conductive shielding, and controlling electrical power supplied to the heating elements to achieve reduction of both electric field and magnetic field components of EMF generated during operation of the radiant heating device.

In step 101, an even number of heating elements are arranged in pairs within a radiant heating device. Each pair includes a first heating element and a second heating element disposed in a spaced configuration relative to each other. The heating elements are configured to emit radiant heat when energized by an alternating current (AC) power source. In some embodiments, the heating elements may comprise halogen infrared tubes, carbon heating elements, carbon fiber heating elements, or other resistive heating elements capable of generating radiant heat.

In some embodiments, the heating elements within each pair are mounted in a generally parallel orientation and separated by a distance on the order of 5 millimeters to 100 millimeters. The paired configuration promotes spatial symmetry between the heating elements, which assists in reducing EMF during operation.

In some embodiments, in step 103, electrical connections are configured such that electrical current supplied to the first heating element flows in a first direction, while electrical current supplied to the second heating element flows in a second direction opposite to the first direction. Each heating element is electrically connected to the AC power source through an electrical circuit configured to establish the opposing current flow. In some embodiments, the AC feed wires supplying current to the heating elements may additionally be twisted around each other, so that the opposing currents in adjacent wire segments cause their respective magnetic fields to cancel along the length of the wire run, further reducing magnetic field emissions from the wiring itself.

When electrical current flows in opposite directions through the paired heating elements, magnetic fields generated by the respective current flows at least partially cancel in the ambient environment surrounding the radiant heating device. In some embodiments, the current supplied to the heating elements may be synchronized so that the magnetic fields generated by the heating elements are substantially opposed in orientation.

In step 105, a conductive shield is positioned in proximity to the heating elements. In some embodiments, the conductive shield may be disposed between the heating elements or between the heating elements and the user-occupied space. The conductive shield may comprise a metallic material selected from the group consisting of aluminum, copper, stainless steel, and electrically conductive alloys.

In some embodiments, the conductive shield may be formed as a planar sheet, perforated metallic panel, mesh structure, or other conductive barrier capable of reducing electric field emissions while allowing radiant heat to propagate from the heating elements. The conductive shield functions to intercept and redirect electric field emissions generated by the energized heating elements.

In some embodiments, in step 107, the conductive shield is electrically connected to earth ground using a grounding conductor. The grounding conductor provides a low-resistance electrical path between the conductive shield and a ground reference.

Electrically connecting the conductive shield to earth ground enables dissipation of electric charges that accumulate on the conductive shield and forms a discharge path for capacitive coupling currents. This configuration suppresses electric field emissions generated by the energized heating elements.

In some embodiments, in step 109, a feed circuit is incorporated into the radiant heating system. The feed circuit is operatively connected to the heating elements and regulates the electrical current supplied to the heating elements. The feed circuit may include a microcontroller, switching devices, relays, or inverter circuitry configured to control polarity, phase, or amplitude of the electrical current supplied to the heating elements.

In some embodiments, the feed circuit ensures that electrical current supplied to the first heating element flows in the first direction and electrical current supplied to the second heating element flows in the second direction opposite to the first direction. The feed circuit may further synchronize or adjust current phasing to enhance magnetic field cancellation.

In some embodiments, in step 111, an optional conductive enclosure may be installed surrounding at least a portion of the radiant heating device. The conductive enclosure may comprise a mesh structure, metallic foil, perforated panel, or other conductive barrier fabricated from aluminum, copper, stainless steel, or conductive polymer laminate.

In some embodiments, the conductive enclosure may function as a secondary shielding structure that further reduces electric field emissions and extends EMF mitigation to regions outside the immediate vicinity of the heating elements.

In step 113, the radiant heating system is activated under normal operating conditions. Electrical power from the AC power source is supplied to the heating elements through the feed circuit, causing the heating elements to generate radiant heat.

During operation, the combination of opposing current flow through the paired heating elements, the conductive shield connected to earth ground, and optional conductive enclosure shielding results in concurrent reduction of electric field and magnetic field components of EMF generated during operation of the radiant heating device.

In some embodiments, the conductive shield described above may comprise a perforated mesh or grid structure. The mesh may include openings on the order of 1 millimeter to 100 millimeters in diameter, allowing radiant heat to pass through while still providing attenuation of electric field emissions. The mesh may be fabricated from conductive materials such as aluminum, copper, stainless steel, or other electrically conductive alloys.

In some embodiments, the conductive shield may be mechanically supported within the radiant heating device using electrically insulating standoffs. The standoffs may be fabricated from electrically insulating and heat-resistant materials including mica, ceramic, polytetrafluoroethylene (PTFE), high-temperature silicone, or similar dielectric materials. The insulating standoffs maintain electrical isolation between the conductive shield and adjacent energized components while preserving structural stability of the shield.

In some embodiments, the radiant heating system described herein may be incorporated into a variety of heating devices including infrared sauna heaters, residential radiant space heaters, therapeutic heating panels, or outdoor infrared heaters. In some embodiments, the system may be integrated into an infrared sauna enclosure in which multiple paired heating elements are positioned along interior walls to provide uniform radiant heating while minimizing EMF exposure to users.

In some embodiments, the optional conductive enclosure surrounding the heating device may include one or more infrared-transparent windows. Such windows may be formed from electrically non-conductive materials that permit transmission of radiant heat while maintaining electrical isolation from the conductive enclosure. Example materials may include borosilicate glass, quartz glass, ceramic glass, or high-temperature infrared-transparent polymers.

In some embodiments, electrical supply wires delivering current to the heating elements may be arranged so that wires carrying simultaneously opposing currents are disposed generally parallel to each other. The separation distance between such wires may be less than a measurement distance at which magnetic field cancellation is evaluated. By maintaining opposing current conductors in close proximity, magnetic fields generated by the conductors may further cancel each other.

In some embodiments, the electrical supply wires carrying opposing currents may additionally be twisted around each other to further enhance magnetic field cancellation. Twisting opposing conductors causes magnetic fields generated by the wires to alternate orientation along the length of the wire pair, thereby reducing net magnetic field emissions.

In some embodiments, the wiring configuration described above may be applied to wiring between heating elements as well as to wiring between the heating elements and the feed circuit. Opposing current conductors may be routed together along substantially the same path in order to maximize cancellation of magnetic fields generated by the electrical supply wiring.

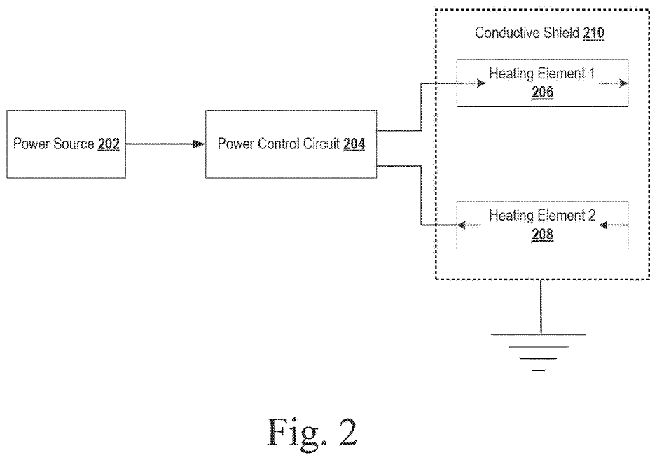

FIG. 2 illustrates a schematic block diagram of an example configuration of a radiant heating system configured to reduce EMF emissions in accordance with certain embodiments of the present invention. As shown in FIG. 2, the system includes a power source 202, a feed circuit 204, a first heating element 206, a second heating element 208, and a conductive shield 210 disposed in proximity to the heating elements.

The power source 202 provides electrical power for operation of the radiant heating device. In some embodiments, the power source 202 may comprise an alternating current (AC) power source such as a residential or commercial electrical supply. In other embodiments, the power source 202 may comprise a direct current (DC) power source, including battery systems, rectified AC supplies, power converters, or other DC power generation or storage systems. In some embodiments, the power source 202 may include a power conversion stage configured to convert AC electrical power to DC electrical power or DC electrical power to AC electrical power as required by the heating elements or control circuitry. The power source 202 provides electrical energy to the feed circuit 204 through electrical conductors that deliver electrical current to the heating system.

The feed circuit 204 is operatively connected to the power source 202 and is configured to regulate and control the electrical current supplied to the heating elements. In some embodiments, the feed circuit 204 may include switching circuitry, relays, semiconductor switching devices, inverter circuits, or a microcontroller-based control system capable of controlling electrical current delivered to the heating elements. The feed circuit 204 may further regulate polarity, phase, or amplitude of electrical current supplied to the heating elements in order to achieve desired operating characteristics.

In some embodiments, the feed circuit 204 may be configured to operate with either AC or DC electrical power supplied by the power source 202. For example, when AC power is supplied, the feed circuit may control the phase, polarity, or waveform of the alternating current delivered to the heating elements. When DC power is supplied, the feed circuit may reverse current direction, modulate current amplitude, or generate alternating current signals to achieve opposing current flow through paired heating elements for magnetic field cancellation.

In the embodiment illustrated in FIG. 2, the feed circuit 204 supplies electrical current to a first heating element 206 and a second heating element 208. The heating elements are configured to emit radiant heat when energized by electrical current from the power source 202. In some embodiments, the heating elements may comprise halogen infrared tubes, carbon heating elements, carbon fiber heating elements, or other resistive heating structures capable of generating radiant heat.

The first heating element 206 and the second heating element 208 may be arranged as a pair of heating elements within the radiant heating device. In some embodiments, the heating elements may be mounted in a generally parallel orientation and positioned in spaced relation to each other. The feed circuit 204 is configured to supply electrical current to the first heating element 206 in a first direction, while electrical current supplied to the second heating element 208 flows in a second direction opposite to the first direction.

By supplying electrical current through the paired heating elements in opposite directions, magnetic fields generated by current flowing through the heating elements are oriented in opposing directions. As a result, the magnetic fields generated by the respective current flows may partially or substantially be cancelled in the ambient environment surrounding the radiant heating device. This opposing-current configuration therefore reduces magnetic field emissions generated during operation of the heating system.

As further illustrated in FIG. 2, a conductive shield 210 is positioned in proximity to the heating elements. In some embodiments, the conductive shield 210 may be disposed between the heating elements or between the heating elements and the user-occupied space. The conductive shield 210 may be fabricated from an electrically conductive material such as aluminum, copper, stainless steel, or other electrically conductive alloys.

The conductive shield 210 functions to attenuate or redirect electric field emissions produced by the energized heating elements. In some embodiments, the conductive shield 210 may be connected to earth ground through a grounding conductor, allowing electric charges induced on the shield to dissipate safely to ground. This grounding configuration reduces electric field emissions generated by the heating elements during operation.

Accordingly, the system configuration illustrated in FIG. 2 demonstrates a radiant heating system in which opposing current flow through paired heating elements reduces magnetic field emissions, while the conductive shield 210 reduces electric field emissions, thereby enabling concurrent reduction of EMF during operation of the radiant heating device.

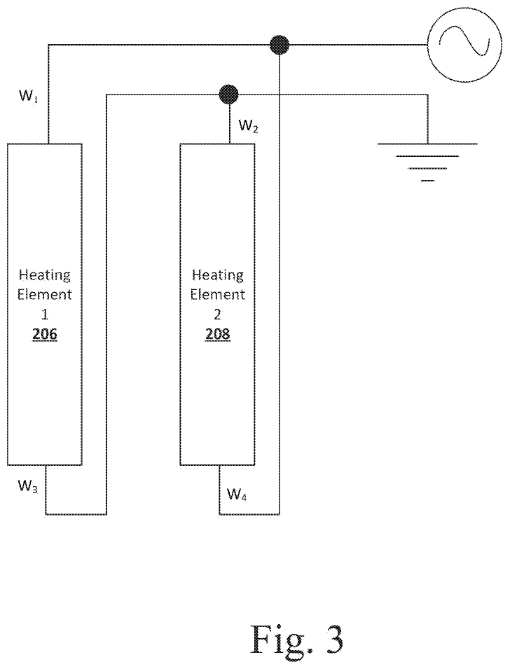

FIG. 3 illustrates an example electrical configuration of paired heating elements within a radiant heating device configured to reduce EMF emissions. In the embodiment shown, a first heating element 206 and a second heating element 208 are electrically connected to a power source. The power source may comprise an alternating current (AC) power source, a direct current (DC) power source, or another electrical power supply capable of energizing the heating elements.

In some embodiments, the first heating element 206 and the second heating element 208 are positioned in proximity to each other, such as in a generally parallel physical arrangement within the radiant heating device. Each heating element is configured to emit radiant heat when an electrical current passes through the heating element.

In some embodiments, as illustrated in FIG. 3, the heating elements are electrically connected such that electrical current flows through the first heating element 206 in a first direction and through the second heating element 208 in a second direction opposite to the first direction. The electrical wiring is arranged so that the current direction through the paired heating elements is reversed relative to each other.

As illustrated in FIG. 3, four feed wires connect the heating elements to the AC power source. Wire 1 (W1) connects the top terminal of heating element 1 (206) to the AC source. Wire 2 (W2) connects the top terminal of heating element 2 (208) to the AC source. Wire 3 (W3) connects the bottom terminal of heating element 1 (206) to the AC return. Wire 4 (W4) connects the bottom terminal of heating element 2 (208) to the AC return. Because the leads of heating element 2 (208) are reversed relative to heating element 1 (206), the current flowing through W1 and W4 is in phase with each other, while the current flowing through W2 and W3 is in phase with each other- and both of those phases are opposite to the other pair. This means that W1 and W2 carry opposing-phase currents, and W3 and W4 carry opposing-phase currents.

In some embodiments, to reduce magnetic field emissions from the feed wiring itself, the wires carrying opposing-phase currents are paired together in close proximity. W3 and W4, which feed the bottom terminals of the two heating elements, carry opposing currents and may be routed together as a wire pair. Because the bottom feed wires may run a longer physical distance—for example along the back of a heater enclosure away from the hot elements—the magnetic field they generate over that length can be significant, and pairing W3 with W4 causes their fields to substantially cancel along the entire wire run. This wire pair may exist in a different physical plane than the plane containing the two heating elements, for example routed behind or beneath the heater housing, without degrading the cancellation so long as the two wires of the pair remain in close proximity to each other. In some embodiments, W3 and W4 may be twisted around each other along their length to further enhance this cancellation. Similarly, W1 and W2 feed the top terminals of the heating elements and also carry opposing-phase currents. Although these wires are shown as shorter runs in FIG. 3, in practice their routed length may be greater, in which case they should likewise be run as a closely spaced or twisted pair to reduce their contribution to the net magnetic field. In some embodiments, W1 and W2 are twisted around each other along their routed length for the same reason. The result is a system in which magnetic field cancellation occurs through three independent mechanisms simultaneously: cancellation between the heating elements themselves, cancellation between the W1/W2 wire pair, and cancellation between the W3/W4 wire pair.

When electrical current flows through a conductor or a resistive heating element, a magnetic field is generated around the conductor. Because current flows through the first heating element 206 and the second heating element 208 in opposite directions, the magnetic fields generated by the respective heating elements are also oriented in opposite directions. As a result, the magnetic fields produced by the heating elements may partially or substantially cancel each other in the ambient environment surrounding the radiant heating device.

In some embodiments, the heating elements may be electrically connected in a parallel electrical configuration, in which each heating element is connected directly across the power source. In some embodiments, substantially the full supply voltage may be applied across each heating element. For example, when the power source supplies approximately 240V AC, each heating element may receive substantially the full supply voltage. This configuration allows each heating element to operate at its intended power level while still providing magnetic field cancellation due to the opposing current flow through the heating elements.

In some embodiments, in addition to magnetic field cancellation between the heating elements themselves, the electrical supply wiring may also contribute to reduction of EMF. Electrical conductors delivering current to the heating elements may be arranged so that wires carrying opposing currents are positioned in close proximity to one another. This arrangement may cause magnetic fields generated by the conductors to oppose and partially cancel each other.

Magnetic field reduction in the system illustrated in FIG. 3 may therefore occur through multiple mechanisms, including: heating element-to-heating element magnetic field cancellation, electrical wire-to-heating element magnetic field cancellation, and electrical wire-to-wire magnetic field cancellation.

These multiple cancellation mechanisms collectively reduce the overall magnetic field emitted by the radiant heating device.

In some embodiments, magnetic field cancellation may be achieved with a single heating element by routing the return wire for that element in close physical proximity to, and parallel with, the heating element itself. As illustrated in FIG. 3, the forward current through heating element 1 (206) flows along the same axis as wire W3, which carries the return current for that element. Because the forward current through the heating element and the return current through W3 flow in opposite directions, their respective magnetic fields oppose each other. By positioning W3 physically close to and parallel with heating element 206, and by orienting the wire pair to minimize the net magnetic field at the distance of concern, substantial cancellation of the magnetic field from that single element and its return wire can be achieved. The best position of the return wire relative to the heating element is one that minimizes the net measurable field at the relevant measurement distance, which as described above depends on the ratio of the separation between the element and its return wire to the measurement distance.

Because a heating element has a significant length, its two electrical terminals are physically separated—one at each end. The forward and return conductors therefore cannot both be routed in proximity along the full length of the element simultaneously; one conductor must connect at one end and the other at the other end. Two approaches to achieving cancellation between the conductors and the heating element are contemplated. In a first approach, the feed conductor is split at an intermediate point along the length of the heating element, with one segment running from the split point to one terminal and the other segment running from the split point to the other terminal. Each segment carries current in the opposite direction to the current in the adjacent portion of the heating element, so that each segment and its adjacent element portion form a local cancellation pair. The location of the split point can be selected to minimize net field at the region of concern and to keep the split point away from the user. In a second approach, as illustrated generally in FIG. 3, one conductor is connected as a short lead at one terminal of the heating element while the other conductor runs as a longer lead to the opposite terminal. In this configuration the long lead runs substantially parallel to and alongside the full length of the heating element, carrying current in the opposite direction to the current in the element, and the two together function as a cancellation pair over that full length. In both approaches, as the conductors leave the heating element terminals they should be routed in close physical proximity to each other, and in some embodiments twisted together, so that the opposing currents in the departing conductor segments cancel each other's magnetic fields along the run back to the source.

This single-element return wire cancellation principle is independent of and complementary to the paired-element cancellation described above. In some embodiments, a system may employ any combination of these mechanisms. For example, a system comprising an odd number of heating elements may pair as many elements as possible using the opposing-current paired configuration—the even-numbered subset of heating elements being arranged in opposing-current pairs—while the remaining unpaired element achieves cancellation by routing its return wire closely alongside it. In some embodiments, a system comprising any number of heating elements, whether even or odd, may achieve cancellation through any combination of: paired heating elements with opposing currents, paired return wires carrying opposing currents, individual heating elements each with their return wire routed in close proximity, or twisted pairs of any of the foregoing. Each such pairing or combination operates as an independent cancellation unit, and multiple such units within a single device contribute additively to the overall reduction of EMF.

In some embodiments, the electrical supply wires carrying opposing currents may be routed in generally parallel paths or may be twisted around each other along portions of their length. Twisting or closely spacing opposing current conductors may further improve cancellation of magnetic fields generated by the electrical wiring.

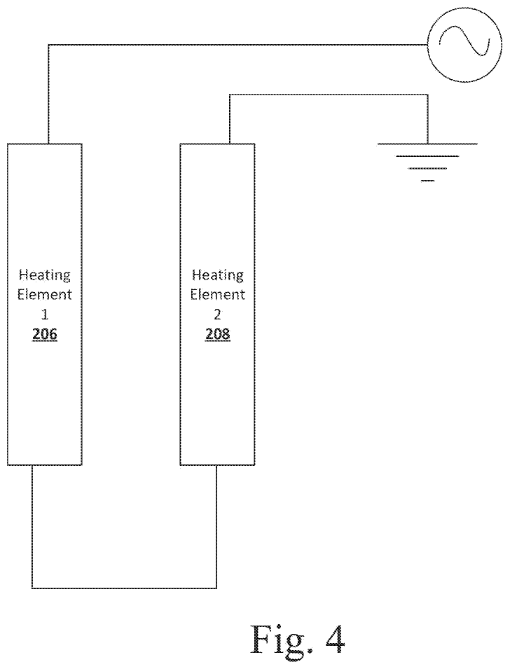

FIG. 4 illustrates another example electrical configuration of paired heating elements within a radiant heating device configured to reduce EMF emissions. As shown in FIG. 4, a first heating element 206 and a second heating element 208 are electrically connected to a power source. The power source may comprise an alternating current (AC) power supply, such as a residential or commercial AC electrical source.

In the embodiment illustrated in FIG. 4, the heating elements are connected in a series electrical configuration, in which electrical current flows sequentially through the first heating element 206 and the second heating element 208. The heating elements may be positioned in a generally parallel physical arrangement within the radiant heating device, while the electrical connections cause the current flowing through the heating elements to be oriented in opposite directions relative to each other. In some embodiments, the AC feed wires supplying current to the series-connected heating elements may additionally be twisted around each other, so that the opposing currents in adjacent wire segments cause their respective magnetic fields to cancel along the length of the wire run, further reducing magnetic field emissions from the wiring itself.

In some embodiments, when connected in series, the total voltage supplied by the power source is divided between the heating elements. For example, when the power source provides approximately 240 volts AC, the electrical voltage across each heating element may be approximately 120 volts, depending on the electrical resistance characteristics of the heating elements. As a result, each heating element may operate at approximately half of the supplied voltage, and the power dissipated by each heating element may be reduced relative to operation at full supply voltage.

Because electrical current flows through the heating elements in opposite directions, the magnetic fields generated by the current flowing through the first heating element 206 and the second heating element 208 are oriented in opposite directions. According to the principles governing electric and magnetic fields, current flowing through a conductor generates a surrounding magnetic field. When adjacent conductors carry current in opposite directions, the resulting magnetic fields may partially or substantially cancel each other in the surrounding environment.

Accordingly, the configuration illustrated in FIG. 4 demonstrates that opposing current directions through paired heating elements can reduce magnetic field emissions generated by the radiant heating device. Although the series connection may result in reduced electrical power delivered to each heating element due to the voltage division across the series circuit, the configuration can still provide beneficial magnetic field cancellation in certain implementations.

The embodiment illustrated in FIG. 4 therefore represents an example configuration in which paired heating elements 206 and 208 are electrically connected in a series arrangement such that opposing current flow produces magnetic fields that oppose each other and contribute to reduction of EMF during operation of the radiant heating device.

What is claimed is:

1. A system for reducing EMF emissions in a radiant heating device, the system comprising:
an even number of heating elements configured to emit radiant heat upon receipt of electrical current, the heating elements being arranged in at least one pair, each pair comprising a first heating element and a second heating element disposed in close proximity to each other;
electrical wiring connecting a power source to the first heating element in a first polarity and to the second heating element in a reversed polarity, such that current flows through the first heating element in a first direction and through the second heating element in a direction opposite to the first direction, the electrical wiring including at least one pair of supply conductors carrying opposing currents routed in close proximity to each other;
a conductive shield disposed between the heating elements and the user-occupied space and electrically connected to an earth ground by a grounding conductor.

2. The system of claim 1, further comprising phase-adjusting circuitry on the feed line of at least one heating element, the phase-adjusting circuitry comprising at least a series circuit element and a shunt circuit element connected in the feed line and together forming a phase-shift network for the current supplied to that heating element.

3. The system of claim 2, further comprising a microcontroller connected to the electrical wiring and to the phase-adjusting circuitry and to one or more magnetic field sensors, the microcontroller being configured to adjust the polarity, phase, or amplitude of the current and to adjust the phase-adjusting circuitry based on measurements from the magnetic field sensors.

4. The system of claim 1, wherein the supply conductors carrying opposing currents are twisted around each other along their routed length.

5. A system for reducing EMF emissions in a radiant heating device, the system comprising:
one or more heating elements configured to emit radiant heat upon receipt of electrical current, each heating element having a first terminal at one end and a second terminal at the other end;
electrical conductors connected to the terminals of each heating element, wherein at least one conductor is routed in close proximity to and parallel with its associated heating element while carrying current in the direction opposite to the current in that heating element;
a conductive shield disposed between the heating elements and the user-occupied space and electrically connected to an earth ground.

6. The system of claim 5, wherein one conductor is connected at the first terminal of the heating element and runs alongside the full length of the heating element parallel to it, and the other conductor is connected at the second terminal.

7. The system of claim 5, wherein the conductor is split at an intermediate point along the length of the heating element, with one segment running from the split point to the first terminal and another segment running from the split point to the second terminal, each segment running in close proximity to the adjacent portion of the heating element and carrying current in the direction opposite to the current in that portion.

8. The system of claim 5, wherein the conductors departing the heating element terminals are twisted around each other along their routed length.

9. The system of claim 5, wherein the one or more heating elements comprise halogen infrared tubes, carbon heating elements, or carbon fiber heating elements.

10. The system of claim 5, wherein the system comprises an odd number of heating elements, the even-numbered subset of heating elements being arranged in opposing-current pairs and the remaining heating element having a conductor routed in close proximity to and parallel with it, the conductor carrying current in the direction opposite to the current in that heating element.

11. The system of claim 5, further comprising phase-adjusting circuitry on the feed line of at least one heating element, the phase-adjusting circuitry comprising at least a series circuit element and a shunt circuit element connected in the feed line and together forming a phase-shift network for the current supplied to that heating element.

12. The system of claim 11, wherein a microcontroller adjusts the phase-adjusting circuitry based on feedback from one or more magnetic field sensors positioned in proximity to the heating elements.

13. The system of claim 5, wherein the radiant heating device is configured for use in an infrared sauna, space heater, outdoor radiant heater, or therapeutic heating panel.

14. The system of claim 5, further comprising a conductive enclosure surrounding at least a portion of the radiant heating device and electrically connected to earth ground.

15. A method for reducing EMF emissions in a radiant heating device, the method comprising:
supplying electrical current to one or more heating elements through electrical conductors connected to terminals at each end of each heating element, the heating elements being configured to emit radiant heat upon receipt of said current;
routing at least one conductor in close proximity to and parallel with its associated heating element and connecting that conductor to carry current in the direction opposite to the current in that heating element;
positioning a conductive shield between the heating elements and the user-occupied space; and
electrically connecting the conductive shield to an earth ground.

16. The method of claim 15, further comprising connecting a feed circuit to supply current to at least two heating elements disposed in close proximity to each other in opposite directions.

17. The method of claim 15, further comprising routing the electrical conductors in close proximity to each other as they depart the heating element terminals.

18. The method of claim 17, wherein the electrical conductors are twisted around each other along at least a portion of their routed length.

19. The method of claim 15, further comprising connecting phase-adjusting circuitry on the feed line of at least one heating element, the phase-adjusting circuitry comprising at least a series circuit element and a shunt circuit element forming a phase-shift network for the current supplied to that heating element.

20. The method of claim 19, further comprising adjusting the phase-adjusting circuitry using a microcontroller based on feedback from one or more magnetic field sensors.
